(19) United States
(12) Patent Application Publication
(10) Pub. No.: US 2023/0209795 A1
(43) Pub. Date: Jun. 29, 2023

(54) SRAM BIT CELLS

(71) Applicant: GLOBALFOUNDRIES U.S. Inc., Malta, NY (US)

(72) Inventors: Ralf van BENTUM, Moritzburg (DE); Karsten FLECK, Dresden (DE)

(21) Appl. No.: 17/560,332

(22) Filed: Dec. 23, 2021

(51) Int. Cl. H01L 27/11; H01L 29/49

(52) U.S. Cl. CPC H01L 27/1104; H01L 29/4966

(57) ABSTRACT

The present disclosure relates to semiconductor structures and, more particularly, to SRAM bit cells and methods of manufacture. The structure includes a p-FET gate structure including p-FET work function material and an n-FET gate structure including the p-FET work function material. Alternatively, the p-FET gate structure includes n-FET work function material, and the n-FET gate structure includes p-FET work function material.

### BACKGROUND

The present disclosure relates to semiconductor structures and, more particularly, to SRAM bit cells and methods of manufacture.

Static Random Access Memory (SRAM) comprises several rows and columns of storage bit-cells called bit-lines (BL and BL′) and word-lines (WL) to control data access and storage. The bit-cells are bi-stable flip-flops which comprise pull-up (PU), pull-down (PD), and pass-gate (PG) transistors. With device scaling, SRAM has become a large component in state-of the-art VLSI systems or Systems-on-Chip (SoC).

At lower technology nodes, the size of a memory cell has been reduced; however, such scaling results in increased leakage current. Such leakage currents can be channel leakage, gate leakage as well as junction and GIDL leakage.

To reduce gate leakage, high-k dielectrics have been introduced. For channel leakage reduction either higher halo/well doses are applied, or longer gate lengths can be used, both to increase the threshold voltage of the transistors. Also, different cell topology can be used to turn-off leakage paths. Longer Lgate or different cell topology have the drawback of higher area consumption, while higher halo and well doses result in increased junction and GIDL leakages. For highly scaled high-k metal gate SRAM bit cells, the junction and GIDL leakages can dominate the total bit cell leakage due to the required high halo doses. For higher halo and well doses also the Vmin window degrades due to increased random dopant fluctuation (Vtmm). Further, to achieve a sufficiently low Vt for logic FETs, p-FETs use a thick layer of cSiGe under the gate to reduce Vt, but this results in difficultly in fabrication processes including the need to grow cSiGe on narrow SRAM p-FETs.

### SUMMARY

In an aspect of the disclosure, a structure comprises a p-FET gate structure comprising p-FET work function material and an n-FET gate structure comprising the p-FET work function material.

In an aspect of the disclosure, a structure comprises a p-FET gate structure comprising n-FET work function material and an n-FET gate structure comprising p-FET work function material.

In an aspect of the disclosure, a method comprises: forming a p-FET gate structure comprising p-FET work function material; and forming an n-FET gate structure comprising p-FET work function material.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a substrate with wells, amongst other features, and related fabrication processes in accordance with aspects of the present disclosure.

FIG. 2 shows angled halo implants, amongst other features, and related fabrication processes in accordance with aspects of the present disclosure.

FIG. 3 shows source/drain diffusions, amongst other features, and related fabrication processes in accordance with aspects of the present disclosure.

FIGS. 4 and 5 show alternate gate structures and related fabrication processes in accordance with aspects of the present disclosure.

### DETAILED DESCRIPTION

The present disclosure relates to semiconductor structures and, more particularly, to SRAM bit cells and methods of manufacture. More specifically, the present disclosure relates to high-k metal gate SRAM bit cells and methods of manufacture. Advantageously, the high-k metal gate SRAM bit cells described herein have reduced leakage and improved low local variation (Vtmm), amongst other improvements and advantages described herein.

In more specific embodiments, the SRAM bit cell comprises a n-FET and a p-FET, where the same work function material may be used for both gate structures of the n-FET and p-FET. More specifically, in embodiments, both the n-FET and p-FET may use the same p-FET work function metal(s). In further embodiments, the n-FET may use the p-FET work function metal(s) and the p-FET may use a n-FET work function metal(s). In yet another embodiment, the p-FET may include a thin layer of SiGe under the p-FET work function metal. In any of these schemes, the required halo implant dosage (and lightly doped drain regions (LDD)) may be reduced, thus improving device performance. That is, it is now possible to use a lower halo dose (and/or LDD) resulting in less dopants in the channel, which reduces Vtmm (local Vt variation) and gate induced drain leakage (GIDL)/junction leakage, while also improving parametric limited Vmin/Vmax yield.

The SRAM bit cells of the present disclosure can be manufactured in a number of ways using a number of different tools. In general, though, the methodologies and tools are used to form structures with dimensions in the micrometer and nanometer scale. The methodologies, i.e., technologies, employed to manufacture the SRAM bit cells of the present disclosure have been adopted from integrated circuit (IC) technology. For example, the structures are built on wafers and are realized in films of material patterned by photolithographic processes on the top of a wafer. In particular, the fabrication of the SRAM bit cells uses three basic building blocks: (i) deposition of thin films of material on a substrate, (ii) applying a patterned mask on top of the films by photolithographic imaging, and (iii) etching the films selectively to the mask.

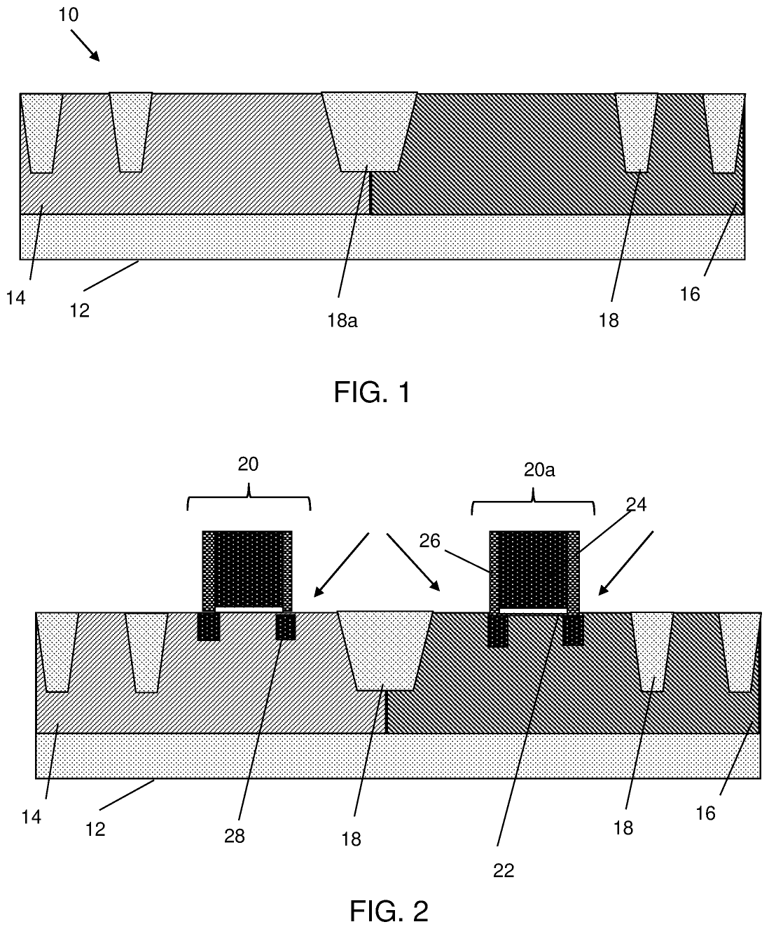

FIG. 1 shows a substrate with wells, amongst other features, and related fabrication processes in accordance with aspects of the present disclosure. More specifically, the structure 10 of FIG. 1 includes a semiconductor substrate 12. The semiconductor substrate 12 is preferably a bulk semiconductor substrate composed of any suitable material. These suitable materials may include, but not limited to, Si, SiGe, SiGeC, SiC, GaAs, InAs, InP, and other III/V or II/VI compound semiconductors.

A p-well 14 and an n-well 16 are formed in the semiconductor substrate 12. In embodiments, the p-well 14 and n-well 16 may be formed by introducing different dopant types in the semiconductor substrate 12 using, for example, ion implantation processes. For example, the wells 14, 16 may be formed by introducing a concentration of a dopant of opposite conductivity type in the semiconductor substrate 12. By way of illustrative example, the p-well 14 is doped with p-type dopants, e.g., Boron (B), and the n-well 16 is doped with n-type dopants, e.g., Arsenic (As), Phosphorus (P) and Sb, among other suitable examples. The dosage of the p-type dopants and n-type dopants may be adjusted to optimize the target Vt.

In embodiments, respective patterned implantation masks may be used to define selected areas exposed for the implantations of the wells 14, 16. The implantation mask used to select the exposed area for forming well 14 is stripped after implantation, and before the implantation mask used to form well 16. Similarly, the implantation mask used to select the exposed area for forming well 16 is stripped after the implantation is performed. The implantation masks may include a layer of a light-sensitive material, such as an organic photoresist, applied by a spin coating process, pre-baked, exposed to light projected through a photomask, baked after exposure, and developed with a chemical developer. Each of the implantation masks has a thickness and stopping power sufficient to block masked areas against receiving a dose of the implanted ions. Also, the dosages of the implants may be adjusted to optimize the target Vt of both n-FET and p-FET devices.

Still referring to FIG. 1, shallow trench isolation structures 18, 18a are formed in the wells 14, 16, with shallow trench isolation structure 18a extending between the wells 14, 16. In embodiments, the shallow trench isolation structures 18, 18a can be formed by conventional lithography, etching and deposition methods known to those of skill in the art. For example, a resist formed over the semiconductor substrate 12 is exposed to energy (light) to form a pattern (opening). An etching process with a selective chemistry, e.g., reactive ion etching (RIE), will be used to transfer the pattern from the patterned resist to the semiconductor substrate 12 to form one or more trenches in the semiconductor substrate 12 through the openings of the resist. Following the resist removal by a conventional oxygen ashing process or other known stripants, insulator material, e.g., oxide material, can be deposited by any conventional deposition processes, e.g., chemical vapor deposition (CVD) processes. Any residual oxide material on the surface of the semiconductor substrate 12 can be removed by conventional chemical mechanical polishing (CMP) processes.

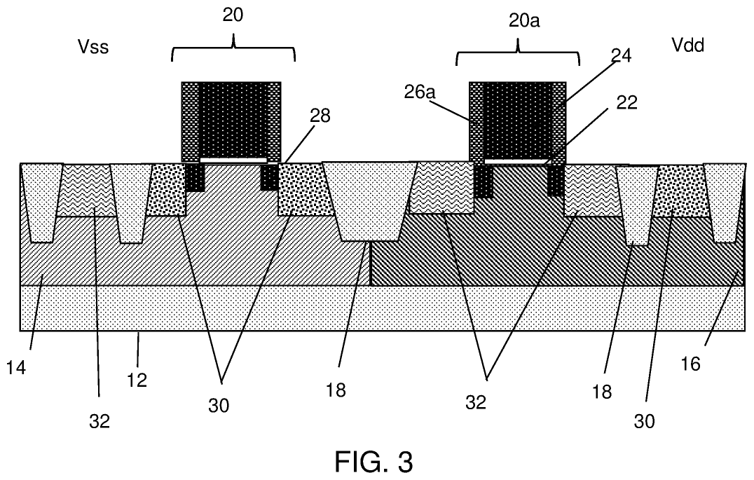

FIG. 2 shows gate structures and respective halo implants, amongst other features, and respective fabrication processes. In embodiments, the gate structures comprise gate structures of a n-FET 20 and p-FET 20a formed by gate first processes; although replacement gate processes are also contemplated herein. In the gate first process, for example, a gate structure for the n-FET 20 is formed over the p-well 14 and a gate structure for the p-FET 20a is formed over the n-well 16 using conventional deposition and patterning processes. For example, the work function metal(s) 24 can be a stack of metals deposited by CVD, physical vapor deposition (PVD) including sputtering, atomic layer deposition (ALD) or other suitable method, as illustrative examples. In embodiments, the gate structures include a thin layer of work function metal with remaining portions being polysilicon.

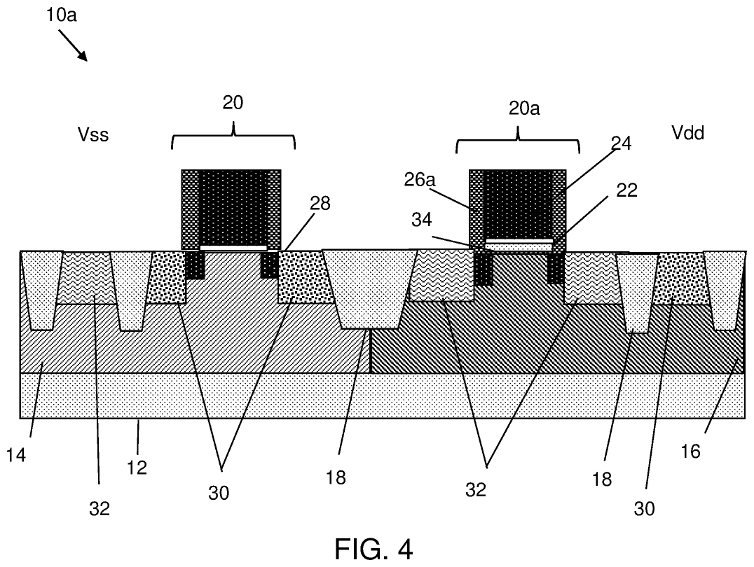

In embodiments, both the gate structures of the n-FET 20 and p-FET 20a comprise a same p-FET work function metal(s) 24. For example, the work function metal(s) 24 for both the n-FET 20 and p-FET 20a may comprise a stack of metals based preferably on Al, e.g., TiN/Al. The use of the p-FET work function metal(s) for the n-FET 20 results in an increase in Vt of approximately 150 to 180 mV of the n-FET 20 (from, e.g., a target Vtsat of about 470 mV to 500 mV in some applications), compared to using n-FET work function metals for the n-FET 20. For example, the Vt can be optimized (e.g., lowered) by adjusting the dosage and/or tilt angle and/or energy of the halo dose, and in embodiments, it is also contemplated to adjust the well dose and dose of the diffusion regions (source/drain regions (LDD)) as shown at reference numeral 30 of FIG. 3 and as described further herein. The gate structures of the n-FET 20 and p-FET 20a also include a polysilicon material over the work function metal(s) 24.

Prior to the deposition of the work function metal(s), a gate dielectric material 22 may be formed on the semiconductor substrate 12. In embodiments, the gate dielectric material 22 may be a high-k gate dielectric material, e.g., HfSiO₂. The gate dielectric material 22 can be deposited using known deposition methods, e.g., ALD or plasma enhance chemical vapor deposition (PECVD) processes.

In this embodiment, the use of SiGe material under the gate dielectric material 22 can be eliminated, resulting in an increase in Vt of approximately 360 mV of the p-FET 20a. It should be understood by those of skill in the art that SiGe material may be present in other devices by removing insulator material prior to gate formation and subsequently growing the SiGe material on the substrate 12. Again, the Vt can be optimized (e.g., lowered) by adjusting the dosage and/or tilt angle and/or energy of the halo implant and/or LDD as described herein. As should be understood by those of skill in the art, the dose required depends significantly on the target Vt, on the tilt angle, the energy and the species. For example, lower energy requires more halo dose, lower tilt angle requires more halo dose as well and vice versa to achieve the same Vt. Hence the specific halo doses depend on all these parameters, in addition to, for example, spacer width and final anneal temperature and duration.

In embodiments and by way of a non-limiting illustrative example, the threshold voltage-reduction of 180 mV for the p-FET work function on the n-FET may be compensated with approximately a 2E13 cm-2 lower halo dose. For the 360 mV for the p-FET (without cSiGe), an approximate 4.5E13 cm-2 reduction is contemplated. To reduce the amount of required halo dose reduction, the tilt angle can be reduced down to 25°, 20° or even 15°, depending on the final optimization of the junction profile. The energy can be reduced to 40 keV, 35 keV or even less, again depending on the final junction profile. Furthermore, in all cases, a reduction of LDD dose/energy may be required. Moreover, the LDD reduction may be different for an n-FET and a p-FET. For example, the n-FET may be between 0E14 cm-2 and 2E14 cm-2 reduction, and the p-FET may be up to 4E14 cm-2. The well implants can be reduced as well to reduce the requirement on the halo dose reduction.

The gate dielectric material 22, work function metal(s) 24 and polysilicon material are patterned using conventional lithography and etching processes, e.g., RIE, to form gate structures for the n-FET 20 and the p-FET 20a. Sidewall spacers 26 may be formed on sidewalls of the patterned gate structures for the n-FET 20 and the p-FET 20a. In embodiments, the sidewall spacers 26 may be an oxide material and/or nitride material deposited by conventional deposition methods, followed by an anisotropic etching process. The anisotropic etching process is known to those of skill in the art such that no further explanation is required for a complete understanding of the present disclosure.

Still referring to FIG. 2, angled halo implants 28 are provided in the semiconductor substrate 12 under the sidewall spacers 26, as represented by the arrows in FIG. 2. The angled halo implant is used to achieve a desired target Vt. For example, in embodiments, the dosage of the angled halo implants 28 may be reduced compared to implant processes for conventional structures, e.g., structures with different work function materials and SiGe material under the gate dielectric material, to achieve a desired target Vt. For example, for the n-FET 20, to achieve a target Vt, the halo dose can be reduced significantly, e.g., reduced by approximately 2E13 cm-2 (from, e.g., 5.7E13 cm-2), to compensate for Vt shift of the work function metal(s) 24. In further embodiments, the tilt angle of the angled halo implants 28 can be adjusted, e.g., decreased, to further adjust for Vt shift. By way of example, the angle of the implant can be reduced to between 25 to 15. In still further embodiments, extension implants and well implants may also be adjusted to achieve a target, optimized Vt as disclosed herein.

By reducing the dosage of the halo implant (and LDD, in some integration schemes), for example, it is now possible to:

(i) reduce high random dopant fluctuation (Vtmm) and drive a higher process window for parametric yield;

(ii) reduce the operating voltage (Vdd);

(iii) provide less abrupt junctions and hence reduce junction/GIDL leakage;

(iv) lower random dopant fluctuation and hence improve Vtmm to improve the array functionality with longer bit lines (e.g., display driver chips);

(v) achieve a same Vtsat and reduced GIDL/junction leakages with a lower dopant concentration compared to conventional structures;

(vi) improve Vmin/Vmax yield for a given Vmin target or Vmin/Vmax for the same parametric yield target for the same bit cell and Vt target;

(vii) widen the process window for Vmin/Vmax operation;

(viii) remove difficult process edges between the n-FET 20 and p-FET 20a;

(ix) avoid the need to grow cSiGe on narrow SRAM p-FETs; and

(x) allow operation in a wider temperature range for same Vdd.

Referring to FIG. 3, additional spacer material 26a may formed over the sidewall spacers in order to properly space away the source/drain diffusions 32 from the gate structures of the n-FET 20 and p-FET 20a. In embodiments, the additional spacer material 26a may be deposited using any known deposition method, followed by another anisotropic etching process as already described herein. The source/drain diffusions 30, 32 are formed within the semiconductor substrate 16 and, more particularly, within the wells 14, 16 on sides of the gate structures of the n-FET 20 and the p-FET 20a, using known implantation processes. In embodiments, the source/drain diffusions 30 are n+ diffusions and the source/drain diffusions 32 are p+ diffusions. The implant dosage can be adjusted as already as described herein to provide many of the advantages described above.

The structure can then undergo back end of line (BEOL) processes, e.g., silicide and contact formation. As should be understood by those of skill in the art, the silicide process begins with deposition of a thin transition metal layer, e.g., nickel, cobalt or titanium, over fully formed and patterned semiconductor devices (e.g., source/drain diffusions 30, 32). After deposition of the material, the structure is heated allowing the transition metal to react with exposed silicon (or other semiconductor material as described herein) in the active regions of the semiconductor device (e.g., source/drain, gate contact region on the polysilicon of the gate structure) forming a low-resistance transition metal silicide. Following the reaction, any remaining transition metal is removed by chemical etching, leaving silicide contacts in the active regions of the device. Contacts may be formed by conventional deposition of insulator material, trench formation in the insulator material by lithography and etching, followed by metal deposition within the trenches for the contacts (followed by chemical mechanical polishing (CMP)).

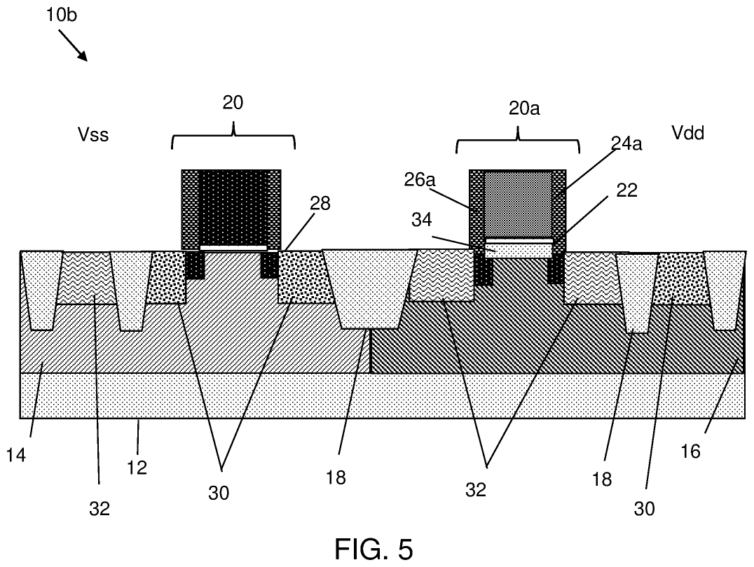

FIG. 4 shows alternate gate structures and related fabrication processes in accordance with aspects of the present disclosure. As in the previous embodiment, the work function metal(s) 24 is the same for both the gate structures of the n-FET 20 and p-FET 20a; however, in the structure 10a of FIG. 4, a thin layer of material 34 is located under the gate dielectric material 22 of the p-FET 20a. In embodiments, the thin layer of material 34 is cSiGe which may be deposited using any known deposition process including an epitaxial growth process, ALD or PECVD. In embodiments, it is possible to reduce the thickness of the layer of material 34 by a conventional thinning process known to those of skill in the art such that no further explanation is required for a complete understanding of the present disclosure. The thickness of the material 34 may be locally thinner compared to other p-FET devices on a same chip in order to reduce the halo dosage for p-FET 20a. For example, the thickness of material 34 may range from 20 Å to 80 Å, and preferably from 20 Å to 500 Å as examples in order to increase the Vt compared to a conventional p-FET device.

The use of the thin layer of material 34 on the p-FET gate 20a results in an increase in Vt of approximately 50 mV to 60 mV of the p-FET 20a. This increase in Vt can be reduced by adjusting the dosage and/or title angle and/or energy of the angled halo implant as already described herein. In this embodiment, the dosage of the halo implant may be reduced less than the dosage used for the halo implant used in the structure 10 of FIGS. 1-3. The benefits of using the structure 10b includes, for example, reducing GIDL/junction leakage and improving Vtmm resulting in an improved Vmin/Vmax window. The remaining features of the structure 10a are similar to that described with respect to FIG. 3.

FIG. 5 shows alternate gate structures and related fabrication processes in accordance with additional aspects of the present disclosure. In this embodiment, the work function metal(s) 24a for the p-FET 20a is a different material than the gate structure used in the n-FET 20. For example, in the structure 10b of FIG. 5, the work function metal(s) 24a for the p-FET 20a can be n-FET work function metal(s) 24a. Examples of the n-FET work function metal(s) may be based on La doped oxides. In further embodiments, the n-FET work function metal(s) may include any known metals, e.g., La doped oxide, or stack of metals. The work function metal 24a may be formed by CVD, PVD including sputtering, ALD or other suitable method. In this embodiment, the layer of material 34 may also be located under the gate dielectric material 22 of the p-FET 20a. In this embodiment, the SiGe material 34 may be any appropriate thickness depending on the desired device performance.

The use of n-FET metal(s) 24a on the p-FET 20a results in an increase in Vt of approximately 150 mV to 180 mV of the p-FET 20a. This increase in Vt can be reduced by adjusting the dosage and/or title angle and/or energy of the angled halo implant as already described herein. In this embodiment, the dosage of the halo implant may be reduced between the dosage required for the structure 10 of FIGS. 1-3 and the halo implant required for the structure 10a of FIG. 4. The benefits of using the structure 10b includes, for example, reducing GIDL/junction leakage and improving Vtmm resulting in an improved Vim/Vmax window. The remaining features of the structure 10b are similar to the structure of FIG. 4.

The SRAM bit cells can be utilized in system on chip (SoC) technology. It should be understood by those of skill in the art that SoC is an integrated circuit (also known as a “chip”) that integrates all components of an electronic system on a single chip or substrate. As the components are integrated on a single substrate, SoCs consume much less power and take up much less area than multi-chip designs with equivalent functionality. Because of this, SoCs are becoming the dominant force in the mobile computing (such as in Smartphones) and edge computing markets. SoC is also commonly used in embedded systems and the Internet of Things.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed:

1. A structure comprising a p-FET gate structure comprising a p-FET work function material and an n-FET gate structure comprising the one or more p-FET work function materials.

2. The structure of claim 1, wherein the p-FET gate structure and the n-FET gate structure comprise high-k metal gate structures comprising the same one or more p-FET work function materials.

3. The structure of claim 2, wherein the p-FET work function material comprises a stack of metal.

4. The structure of claim 2, wherein the p-FET work function material comprises a stack of metals based on Al.

5. The structure of claim 2, wherein the p-FET work function material comprises TiAlC, TiAl, or TaAlC.

6. The structure of claim 2, wherein the p-FET gate structure is devoid of a SiGe layer under the p-FET work function material.

7. The structure of claim 2, wherein the p-FET gate structure further comprises a layer of SiGe under the p-FET work function material.

8. The structure of claim 2, further comprising polysilicon on the p-FET work function material.

9. The structure of claim 1, further comprising different halo implants under the p-FET gate structure and the n-FET gate structure.

10. The structure of claim 1, further comprising a layer of SiGe material under the p-FET work function material of the p-FET gate structure.

11. A structure comprising a p-FET gate structure comprising a n-FET work function material and an n-FET gate structure comprising p-FET work function material.

12. The structure of claim 11, wherein the p-FET gate structure and the n-FET gate structure comprise high-k metal gate structures.

13. The structure of claim 12, wherein the p-FET gate structure further comprises a layer of SiGe under the p-FET work function material.

14. The structure of claim 13, wherein the p-FET work function material comprises a stack of metal.

15. The structure of claim 14, wherein the stack of metal comprises a stack of metals based on Al.

16. The structure of claim 13, wherein the p-FET work function material comprises TiAlC, TiAl, or TaAlC.

17. The structure of claim 13, wherein the n-FET work function material comprises La doped oxides.

18. The structure of claim 13, further comprising a halo implant under the p-FET gate structure and the n-FET gate structure.

19. The structure of claim 13, wherein the layer of SiGe comprises a thickness of approximately 20 Å to 500 Å.

20. A method comprising:
forming a p-FET gate structure comprising p-FET work function material; and
forming an n-FET gate structure comprising the p-FET work function material.
